(19) United States
(12) Patent Application Publication
(10) Pub. No.: US 2026/0323897 A1
(43) Pub. Date: Oct. 15, 2026

(54) ELECTRONIC DEVICE

(71) Applicant: COMPAL ELECTRONICS, INC., Taipei City (TW)

(72) Inventors: Min-Chun Hsieh, Taipei City (TW); Jui-Hung Lai, Taipei City (TW); Wen-Feng Tsai, Taipei City (TW)

(73) Assignee: COMPAL ELECTRONICS, INC., Taipei City (TW)

(21) Appl. No.: 19/281,751

(22) Filed: Jul. 27, 2025

(30) Foreign Application Priority Data
Apr. 10, 2025 (TW) 114113517

(51) Int. Cl. H05K 9/00; G06F 1/16

(52) U.S. Cl. CPC H05K 9/0041; G06F 1/1658; H05K 9/0022; H05K 9/0049

(57) ABSTRACT

An electronic device includes a housing, a plurality of frequency selective surface (FSS) elements and a plurality of electronic elements. The housing includes a heat dissipation area. The FSS elements are disposed in the heat dissipation area of the housing. Each of the FSS elements includes a hole. The electronic elements are disposed in the housing, and the heat generated by the electronic elements is discharged from the heat dissipation area through the holes of the FSS elements.

### CROSS-REFERENCE TO RELATED APPLICATION

This application claims the priority benefit of Taiwan application serial no. 114113517, filed on Apr. 10, 2025. The entirety of the above-mentioned patent application is hereby incorporated by reference herein and made a part of this specification.

### BACKGROUND

### Technical Field

The disclosure relates to an electronic device.

### Description of Related Art

The computing speed of the electronic elements (such as computing units, data processing units, and solid-state drives, etc.) used in the modern electronic device is becoming faster and faster, and the noise and the heat generated when the electronic elements operate are also increasing accordingly. In order to filter the noise of the electronic elements, the electronic device may use metal shielding cases to cover the electronic elements, but the metal shielding masks are closed-type masks, which causes poor heat dissipation convection thereof. The electronic elements cannot dissipate heat effectively, thereby causing poor heat dissipation performance of the electronic device.

### SUMMARY

The disclosure provides an electronic device, which may filter the noise and have better heat dissipation performance.

The electronic device of the disclosure includes a housing, a plurality of frequency selective surface (FSS) elements and a plurality of electronic elements. The housing includes a heat dissipation area. The FSS elements are disposed in the heat dissipation area of the housing. Each FSS element includes a hole. The electronic elements are disposed in the housing, and the heat generated by the electronic elements is discharged from the heat dissipation area through the holes of the FSS elements.

Based on the above, the electronic device of the disclosure utilizes the FSS elements to filter the noise generated during operation of the electronic elements, while facilitating heat dissipation from the electronic elements through the holes of the FSS elements. Thereby, the electronic device has better heat dissipation performance while filtering the noise generated by the electronic elements.

### BRIEF DESCRIPTION OF THE DRAWINGS

FIG. 1 is a schematic diagram of an electronic device according to an embodiment of the disclosure.

FIG. 2 is a partially enlarged view of the electronic device in FIG. 1.

FIG. 3 is a schematic diagram of the frequency selective surface element in FIG. 1.

FIG. 4 is a schematic diagram of an electronic device according to another embodiment of the disclosure.

### DESCRIPTION OF THE EMBODIMENTS

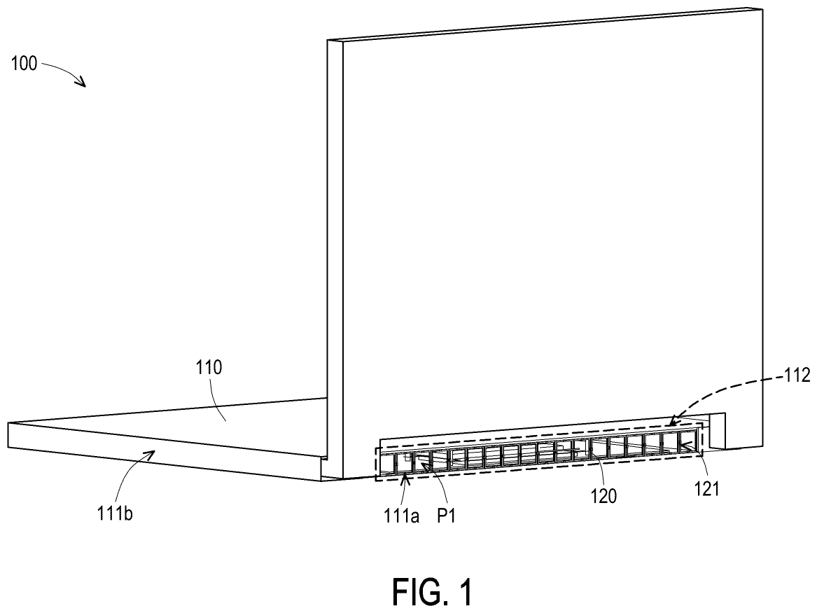

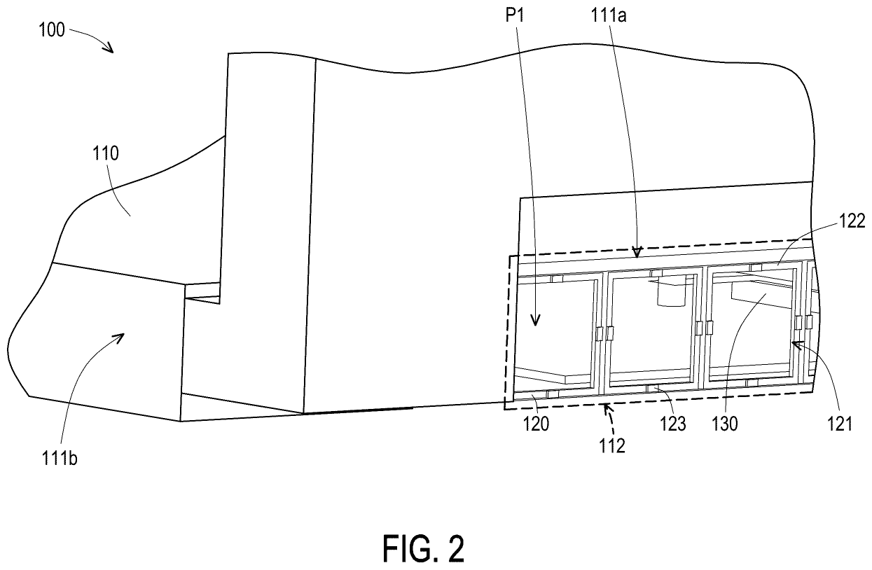

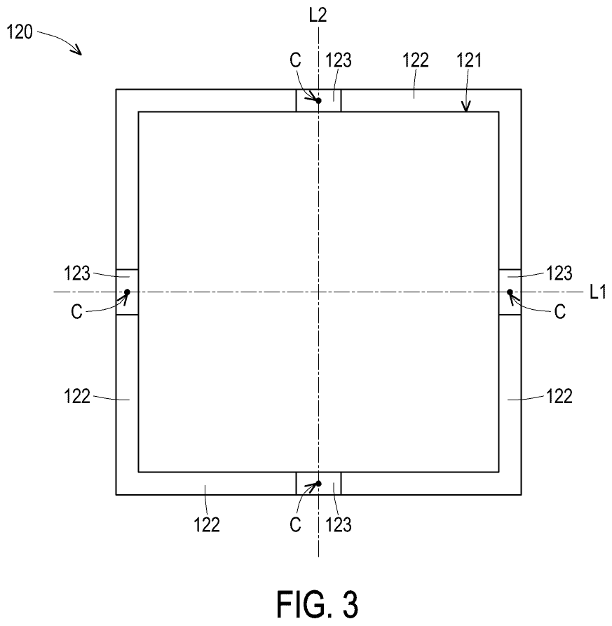

FIG. 1 is a schematic diagram of an electronic device according to an embodiment of the disclosure. FIG. 2 is a partially enlarged view of the electronic device in FIG. 1. FIG. 3 is a schematic diagram of the frequency selective surface element in FIG. 1. Please refer to FIG. 1 to FIG. 3, the electronic device 100 includes a housing 110, a plurality of frequency selective surface

(FSS) elements 120 and a plurality of electronic elements 130. In this embodiment, the electronic device 100 is, for example, a laptop computer, and the electronic elements 130 include a computing unit (CPU) and a graphic processing unit (GPU). The electronic elements 130 may, for example, be disposed on a circuit board (not shown), but not limited thereto. The housing 110 includes a heat dissipation area 112 and an accommodation space P1 adjacent to the heat dissipation area 112. The FSS elements 120 are disposed in the heat dissipation area 112 of the housing 110, used to filter the noise. Each of the FSS elements 120 has a hole 121. The electronic elements 130 are disposed in the accommodation space P1 of the housing 110, so that the heat generated during operation of the electronic elements 130 may be discharged from the heat dissipation area 112 through these holes 121.

Thereby, the electronic device 100 utilizes the FSS elements 120 to filter the noise generated by the electronic elements 130, and also facilitates heat dissipation through the holes 121 of the FSS elements 120, to enhance the heat dissipation performance of the electronic device 100.

As shown in FIG. 1 and FIG. 2, the heat dissipation area 112 of this embodiment is at least one side wall of the housing 110. The housing 110 includes four side walls 111a, 111b. One side wall 111a of the housing 110 is connected to the FSS elements 120, such that the holes 121 of the FSS elements serve as communication openings between the accommodation space P1 of the housing 110 and the external environment, thereby the heat generated by the electronic elements 130 may be discharged to the outside. The side wall 111a forms an open side wall through the holes 121 of the FSS elements 120. The other three side walls 111b of the housing 110 may be the closed side walls, meaning that the side walls 111b do not include the communication openings that can communicate with the external environment. The material of the housing 110 is plastic, but not limited thereto. In an embodiment not shown, the heat dissipation area 112 may be the four side walls of the housing 110, and the FSS elements 120 may be connected to the four side walls to form four open side walls 111a. In this embodiment, the material of the housing 110 may be a metal.

As shown in FIG. 2 and FIG. 3, the FSS element 120 includes a plurality of frames 122 connected to each other, and the frames 122 surround the hole 121. The FSS element 120 of this embodiment is an integrally formed metal member, and the shape formed by the interconnection of the frames 122 defines the shape of the hole 121, but not limited thereto. The number of the frames 122 may be 1 or an even number greater than 2, but not limited thereto. The FSS element 120 includes at least two symmetry axes L1, L2, and the symmetry axes L1, L2 may be perpendicular to each other, but not limited thereto. In this embodiment, the FSS element 120 includes four frames 122, and the four frames 122 are connected to form a square, so that the shape of the hole 121 is a square. In an embodiment not shown, the number of the frames 122 of the FSS element 120 may be one, the frame 122 may be a circle, and the hole 121 may be a circle hole. In an embodiment not shown, the side wall 111a of the housing 110 may be a carrier board of the FSS element 120. The frame 122 may be a metal layer coated on the side wall 111a, and the hole 121 may be located on the side wall 111a. A material of the side wall 111a may be a plastic. The disclosure does not limit the manufacturing method and type of the FSS element 120.

Each of the FSS elements 120 further includes a plurality of lumped elements 123. The lumped elements 123 are respectively disposed on the frames 122. The lumped elements 123 of this embodiment are inductive components, such as a 0402 inductor or a 0201 inductor, but not limited thereto. The FSS element 120 may be considered as a resonant circuit with inductance and capacitance in series. Refer to the resonant frequency formula of the resonant circuit shown below, wherein Lt is the sum of the inductance values of the frames 122 and the inductance values of the lumped elements 123, and Ct is the sum of the capacitance values of the frames 122 and the capacitance values of the lumped elements 123. Since the lumped elements 123 of this embodiment are the inductive components, the total capacitance Ct is the sum of the capacitance values of the frame 122.

$${F}_{resonator frequency} = \frac{1}{2 π \sqrt{{L}_{t} \times {C}_{t}}}$$

In a FSS element without the lumped elements 123, the FSS element increases the total inductance Lₜ or total capacitance Cₜ by increasing the area, to adjust the resonant frequency to a specific value. This will cause the volume (the area) of the FSS element without lumped elements 123 to be too large and inconvenient to use. The FSS element 120 of this embodiment increases the total inductance Lₜ by the lumped elements 123, thereby reducing the area of the FSS element 120, making the FSS element 120 convenient to use. In an embodiment not shown, the lumped elements 123 may be capacitive components or a combination of capacitive-inductive components, to increase the total capacitance Cₜ and/or total inductance Lₜ of the FSS element 120.

The number of the lumped elements 123 is an even number greater than 2, and the lumped elements 123 are arranged symmetrically. In this embodiment, the number of the lumped elements 123 may be equal to the number of the frames 122, and each of the lumped elements 123 is positioned at a geometric center C of each of the corresponding frames 122, but not limited thereto. As shown in FIG. 3, the number of lumped elements 123 in this embodiment is four, and the four lumped elements 123 are respectively disposed at the centers of the corresponding four frames 122. Since the FSS element 120 is considered as the resonant circuit with inductance and capacitance in series, the FSS element 120 can reduce the its volume by increasing the total inductance Lₜ or total capacitance Cₜ through the lumped elements 123. The FSS element 120 also provides a more consistent filtering effect for noise incident from different directions through the lumped elements 123 arranged symmetrically along symmetry axes L1, L2.

In an embodiment not shown, the FSS element 120 may include the four arc-shaped frames 122 and the four lumped elements 123. The four arc-shaped frames may be configured to surround a circular opening, and the four lumped elements 123 may be disposed between two adjacent ends of the four arc-shaped frames 122.

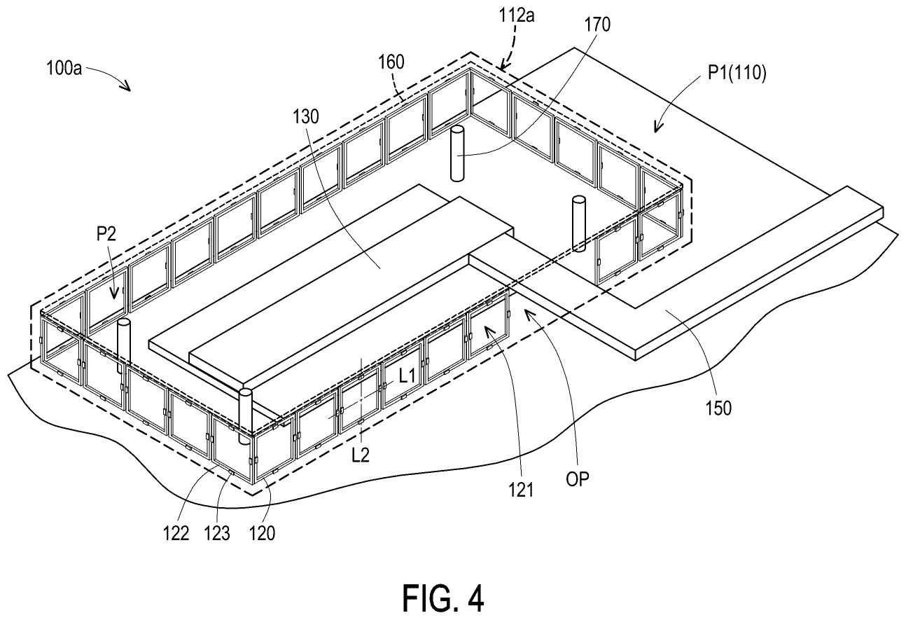

FIG. 4 is a schematic diagram of an electronic device according to another embodiment of the disclosure. Please refer to FIG. 1 and FIG. 4, the electronic device 100a of this embodiment is similar to the previous embodiment. The difference between the two is that the heat dissipation area 112a of this embodiment is located in the accommodation space P1 of the housing 110. The electronic device 100a further includes a cover plate 160 and a connecting element 170. The FSS elements 120 are interconnected in the heat dissipation area 112a to enclose a noise shielding space P2. The electronic element 130 may be disposed in the noise shielding space P2, and located in the heat dissipation area 112a. The cover plate 160 may be coupled to the FSS elements 120, and covers the electronic element 130 located in the noise shielding space P2. The cover plate 160 is connected to the housing 110 or the circuit board through the connecting element 170, and there is a gap between the cover plate 160 and the FSS elements 120. That is, the cover plate 160 does not directly contact the FSS elements 120. The holes 121 of the FSS elements 120 are configured to be communication openings between the accommodation space P1 and the noise shielding space P2. The heat generated by the electronic element 130 is discharged from the noise shielding space P2 (the heat dissipation area 112a) through the holes 121, and exits the electronic device 100a via a heat dissipation hole (not shown) of the housing 110. The FSS elements 120 may be disposed on the circuit board, but not limited thereto. The cover plate 160 of this embodiment is a metal plate. In an embodiment not shown, FSS elements may be disposed on the cover plate 160.

The FSS elements 120 of this embodiment are arranged in a C-shape to form an opening OP, but not limited thereto. A wiring 150 of the electronic device 100a is connected to the electronic element 130 located in the noise shielding space P2, and exits the noise shielding space P2 via the opening OP. An antenna (not shown) of the electronic device 100a is disposed outside the noise shielding space P2. The method of the arrangement of the FSS elements 120 is not limited to the previous embodiments. In an embodiment not shown, the number of the heat dissipation areas may be two. One of the heat dissipation area may be the side wall 111a of the housing 110, and the other of heat dissipation area may be located in the accommodation space P1 of the housing 110. The method of the arrangement of the FSS elements 120 may be a combination of the previous embodiments. In an embodiment not shown, the FSS elements 120 may completely surround the noise shielding space P2 without forming an opening OP.

In summary, the electronic device of the disclosure utilizes the FSS elements to filter the noise generated during operation of the electronic elements, while facilitating heat dissipation from the electronic elements through the holes of the FSS elements. Thereby, the electronic device has better heat dissipation performance while filtering the noise generated by the electronic elements.

What is claimed is:

1. An electronic device, comprising:
a housing, comprising a heat dissipation area;
a plurality of frequency selective surface elements, disposed in the heat dissipation area of the housing, each of the frequency selective surface elements comprises a hole; and
a plurality of electronic elements, disposed in the housing, the heat generated by the electronic elements is discharged from the heat dissipation area through the hole of each of the frequency selective surface elements.

2. The electronic device according to claim 1, wherein the heat dissipation area is at least one side wall of the housing.

3. The electronic device according to claim 1, wherein each of the frequency selective surface elements comprises a plurality of frames connected to each other, the frames surround the hole.

4. The electronic device according to claim 3, wherein the number of the frames is greater than 2 and is an even number.

5. The electronic device according to claim 3, wherein each of the frequency selective surface elements comprises a plurality of lumped elements, each of the lumped elements is connected to each of the frames.

6. The electronic device according to claim 5, wherein each of the lumped elements is positioned at a geometric center of each of the frames.

7. The electronic device according to claim 5, wherein the number of the lumped elements of each of the frequency selective surface elements is equal to the number of the frames.

8. The electronic device according to claim 1, wherein each of the frequency selective surface elements comprises a frame, the frame surrounds the hole, and the shape of the frame is a circular.

9. The electronic device according to claim 1, the housing comprises an accommodation space, the heat dissipation area is located in the accommodation space, and the frequency selective surface elements are connected to each other to surround the electronic elements.

10. The electronic device according to claim 9, further comprising a cover plate, the cover plate covers the electronic elements, and there is a gap between the cover plate and the frequency selective surface elements.
